(19) United States
(12) Patent Application Publication
(10) Pub. No.: US 2009/0296080 A1
(43) Pub. Date: Dec. 3, 2009

(54) METHOD AND APPARATUS FOR MEASURING DEFORMATION OF LAMINATED BODY

(75) Inventors: Dong Jin KIM, Gwangmyeong (KR); Sung Kyu Ha, Ansan (KR); Hyo Jung Kim, Suwon (KR); Ju Ho Kim, Yongin (KR); Dae Bok Oh, Seoul (KR); Won Seop Choi, Suwon (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 12/398,462

(22) Filed: Mar. 5, 2009

(30) Foreign Application Priority Data
Jun. 3, 2008 (KR) 10-2008-0052030
Jun. 3, 2008 (KR) 10-2008-0052206

(51) Int. Cl. G01N 21/00; H01L 21/66; B41J 2/01

(52) U.S. Cl. 356/237.2; 438/15; 347/107

(57) ABSTRACT

There is provided a method of measuring deformation of a laminated body, the method including: laminating and pressurizing a plurality of green sheets each having a plurality of inner electrodes arranged therein to form a laminated body having a plurality of unit chips arranged therein; marking location information of each of the unit chips on an XY plane of the laminated body on a surface of the unit chip; cutting the laminated body into the plurality of unit chips; measuring a deformation level of each of the cut unit chips; and storing the deformation level measured from the each of the cut unit chips to correspond to the location information of the unit chip.

### CROSS-REFERENCE TO RELATED APPLICATIONS

This application claims the priority of Korean Patent Application Nos. 2008-52030 and 2008-52206 filed on Jun. 3, 2008 respectively in the Korean Intellectual Property Office, the disclosure of which is incorporated herein by reference.

### BACKGROUND OF THE INVENTION

1. Field of the Invention

The present invention relates to a method and apparatus for measuring deformation of a laminated body, and more particularly, to a method and apparatus, in which a deformation level of each of unit chips is measured as data during lamination and pressurization in a laminated body having the unit chips arranged in order to measure deformation of the laminated body.

2. Description of the Related Art

In general, a multilayer ceramic capacitor is a chip-type capacitor mounted on a printed circuit board of diverse electronic products such as a mobile telecommunication terminal, a lap top, a personal computer and a personal portable terminal to importantly serve to charge or discharge electricity. The multilayer ceramic capacitor is varied in size and lamination configuration according to use and capacity.

A ceramic laminated body having a plurality of laminated ceramic capacitors formed simultaneously thereon is manufactured through following processes. A slurry-type ceramic is coated successively to a small thickness of several to tens of micro meters on a polyethylene terepthalate (PET) film. The coated ceramic is dried and cut to form a green sheet. A predetermined pattern is printed on a surface of the green sheet. The plurality of green sheets each having the pattern printed thereon are laminated and the laminated body is pressurized under a predetermined pressure.

FIG. 1 is an exploded perspective view illustrating a conventional ceramic laminated body for manufacturing a laminated ceramic capacitor.

Referring to FIG. 1, a ceramic laminated body 100 is formed by laminating a plurality of ceramic green sheets 111, 112, 113, 114, and 115 therein.

A conductor pattern 121 and 131 is formed on each of the ceramic green sheets to form an internal electrode. Here, the internal electrode is formed on the each ceramic green sheet to form the multilayer ceramic capacitor.

To form the multilayer ceramic capacitor, the laminated body may be divided into unit chips and sintered. The laminated body is cut along dotted lines indicated in the drawing into a plurality of laminated ceramic capacitor chips each having the internal electrode exposed on one side surface thereof.

The ceramic laminated body is subjected to pressurization at a predetermined temperature and pressure to be formed. The pressure applied during this pressurizing process may deform the ceramic laminated body. Accordingly, this changes position of the internal electrode on the green sheet. Also, such deformation leads to a difference between a design value and a measured value of the ceramic laminated body.

### SUMMARY OF THE INVENTION

An aspect of the present invention provides a method and apparatus for measuring deformation of a laminated body in which a level of deformation of a laminated body caused by a pressurizing condition during formation of a ceramic body is stored as data and the data is used as a reference in forming the laminated body later.

According to an aspect of the present invention, there is provided a method of measuring deformation of a laminated body, the method including: laminating and pressurizing a plurality of green sheets each having a plurality of inner electrodes arranged therein to form a laminated body having a plurality of unit chips arranged therein; marking location information of each of the unit chips on an XY plane of the laminated body on a surface of the unit chip; cutting the laminated body into the plurality of unit chips; measuring a deformation level of each of the cut unit chips; and storing the deformation level measured from the each of the cut unit chips to correspond to the location information of the unit chip.

The marking may include performing one of laser printing and ink jet printing.

The marking may include printing a bar code indicating the location information of the unit chip.

The measuring a deformation level may include photographing six surfaces of the cut unit chip.

The storing the deformation level may include storing as data a difference between a design value and a measured value of the unit chip.

The unit chip may be a multilayer ceramic capacitor.

According to another aspect of the present invention, there is provided an apparatus for measuring deformation of a laminated body, the apparatus including: a marker marking location information of each of a plurality of unit chips on an XY plane of a laminated body where the plurality of unit chips are arranged on a surface of the each of the unit chips; a cutter cutting the marked laminated body into the unit chips; a measurer measuring a deformation level of the cut unit chips; and a storage storing the measured deformation level to correspond to the location information.

The marker may include one of a laser printer and an ink jet printer.

The measurer may include a photographing device photographing six surfaces of the each of the cut unit chips.

According to still another aspect of the present invention, there is provided a method of marking a laminated body, the method including: forming a laminated body where a plurality of unit chips formed by alternately laminated internal electrodes and green sheets are arranged, the laminated body having indices for separating the unit chips from one another; recognizing the indices; estimating a location of a marking area in each of the unit chips which are to be divided, based on information of the recognized indices; and marking location information of the each unit chip on a XY plane of the laminated body on the estimated marking area.

The recognizing the indices may include scanning four side surfaces of the laminated body, respectively.

The scanning four side surfaces of the laminated body, respectively may include scanning two opposing ones of the side surfaces and the other two opposing side surfaces in an identical direction, respectively.

The scanning of the two opposing ones of the side surfaces and the scanning of the other two opposing side surfaces may be performed simultaneously.

The scanning four side surfaces of the laminated body, respectively may include recognizing all of the indices on one of the side surfaces of the laminated body sequentially.

The estimating may include disposing the marking area between the two successively recognized indices.

The method may further include: dividing the indices into a plurality of index areas by a predetermined pitch; and repeating the recognizing, the estimating and the marking for each of the divided index areas.

According to yet another aspect of the present invention, there is provided a marking apparatus including: an index scanner recognizing indices of a laminated body having the indices for separating unit chips from one another; an estimator estimating a location of a marking area in each of the unit chips which are to be divided, based on information of the indices recognized by the index scanner; and marking location information of each of the unit chips on an XY plane of the laminated body on the marking area estimated by the estimator.

The index scanner may include a photographing device photographing side surfaces of the laminated body.

The marker may include a laser printer.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is an exploded perspective view illustrating a conventional laminated body;

FIGS. 2A to 2E sequentially illustrate a method of measuring deformation of a laminated body according to an exemplary embodiment of the invention;

FIG. 3 is a schematic view illustrating a process of measuring a deformation level of a unit chip in a method of measuring deformation of a laminated body according to another exemplary embodiment of the invention;

FIG. 4 is a configuration view illustrating an apparatus for measuring deformation of a laminated body according to an exemplary embodiment of the invention;

FIGS. 5A to 5D sequentially illustrate a marking process according to an exemplary embodiment of the invention;

FIG. 6 is an exploded perspective view illustrating a laminated body according to an exemplary embodiment of the invention;

FIG. 7 is a procedural view lustrating a marking process according to another exemplary embodiment of the invention; and

FIG. 8 is a configuration view illustrating a marking apparatus according to an exemplary embodiment of the invention.

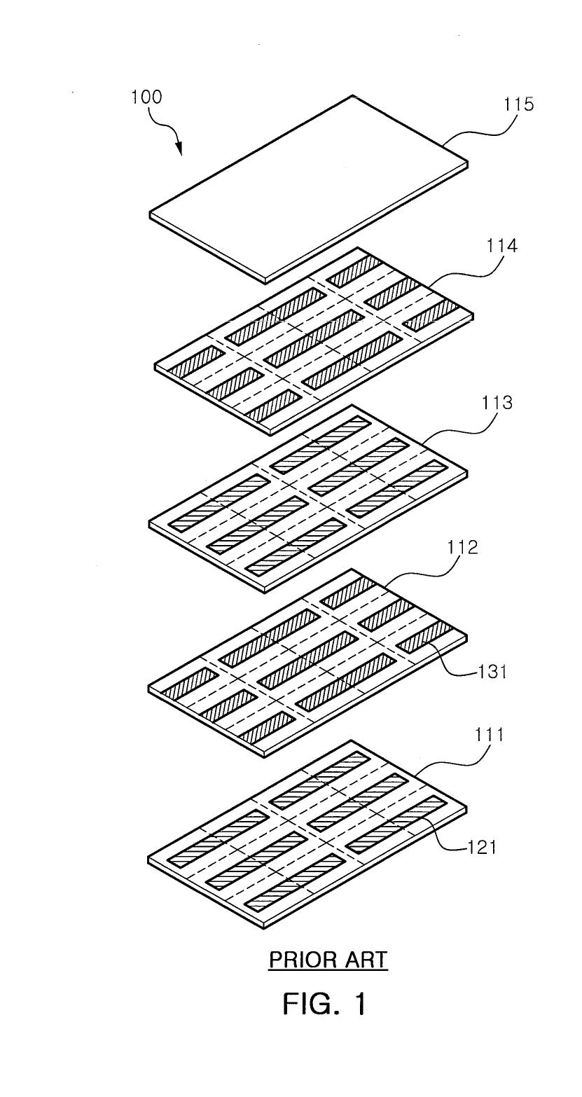

### DETAILED DESCRIPTION OF THE PREFERRED EMBODIMENT

Exemplary embodiments of the present invention will now be described in detail with reference to the accompanying drawings.

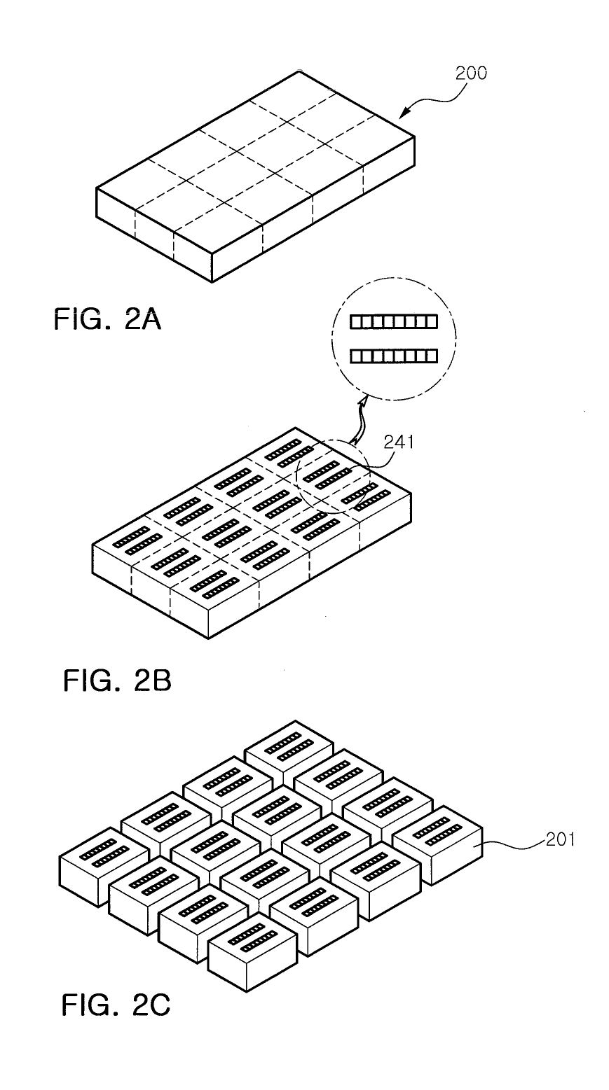

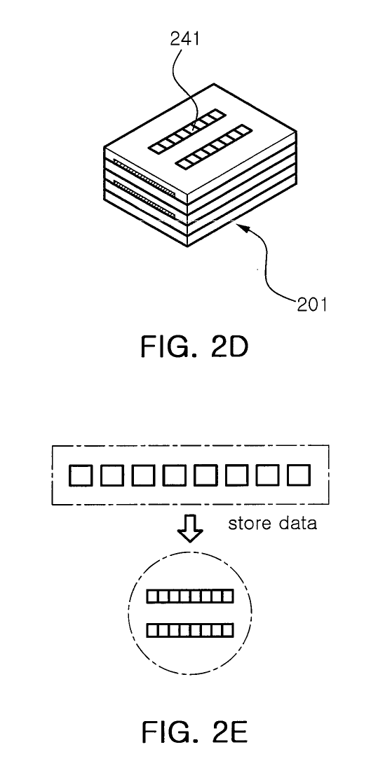

FIGS. 2A to 2E sequentially illustrate a method of measuring deformation of a laminated body according to an exemplary embodiment of the invention.

Referring to FIGS. 2A to 2E, in order to measure deformation of the laminated body according to the present embodiment, the laminated body is formed in process (2A), marked in process (2B), and divided into unit chips in process (2C). Also, a deformation level of each of the unit chips is measured in process (2D) and the deformation level is stored in process (2E).

Referring to FIG. 2A, the laminated body is formed.

In the present embodiment, the laminated body may be formed by laminating a plurality of green sheets. Conductor patterns for a plurality of internal electrodes may be arranged on each of the green sheets. The laminated body having the plurality of internal electrodes laminated therein may be separated into a plurality of unit chips by the conductor patterns for internal electrodes.

In order to form the laminated body, the plurality of green sheets are laminated and pressurized at a predetermined temperature and pressure. At this time, the pressurizing process may cause deformation of the conductor patterns for internal electrodes formed inside the laminated body. In the drawing, deformation of the laminated body is not clearly illustrated but it is construed that an actual measured value of the laminated body differs from a design value of the laminated body.

In the present embodiment, the unit chips are divided by dotted lines on the laminated body. The dotted lines are not actually formed on the actual laminated body but arbitrarily drawn for dividing the unit chips of the laminated body.

Referring to FIG. 2B, location information of the each of the unit chips on an XY plane of the laminated body is marked on the each unit chip.

On the laminated body, the each unit chip may have the location information on an XY plane. In the present embodiment, the laminated body may be divided into 4×3 number of unit chips. The each unit chip can be indicated with XY coordinates. The location information formed on the each unit chip indicates in which column and row the unit chip is located on the laminated body.

In the present embodiment, to mark the location information, a bar code 241 may be marked. The bar code is formed of 2 rows and capable of storing 8-bit data, thereby storing the column and row of the each unit chip. This location information can be marked by various methods.

The location information may be marked by laser printing or ink jet printing. In the case of marking the location information with the bar code, the bar code can be printed on a predetermined marking area by laser printing or ink jet printing.

Referring to FIG. 2C, the laminated body is divided into the unit chips.

In dividing the laminated body into the unit chips, the laminated body may be cut via a blade. To facilitate this cutting process, indices indicating to-be-cut portions may be formed on side surfaces of the laminated body. In this process, the indices are photographed and the blade is positioned where the indices are formed, and then the cutting process is carried out.

Here, to ensure that the blade cuts the indices on the laminated body precisely, the laminated body may be finely rotated to the left and right to be adjusted to a precise position.

Through this process, the laminated body can be divided into a plurality of unit chips 201 and the location information on an XY plane of the laminated body is indicated with a marking 241 on a surface of each of the divided unit chips.

Referring to FIG. 2D, a deformation level of the each of the divided unit chips is measured.

In the present embodiment, to measure the deformation level of the unit chip, six surfaces of the each unit chip may be photographed.

By photographing the six surfaces of the divided unit chip 201, deformation of internal electrodes formed between the laminated green sheets can be observed. That is, photographing of the side surfaces of the each divided unit chip shows that the conductor patterns for internal electrodes formed between the laminated green sheets result in difference in light and shade. This difference in light and shade allows for observation of the shape of the conductor patterns of internal electrodes formed in the laminated body. Accordingly, this enables a comparison between the conductor patterns for internal electrodes formed on the green sheets before the lamination process and the conductor patterns for internal electrodes deformed after the lamination process.

Referring to FIG. 2E, the deformation level measured is stored to correspond to the location information marked on the unit chip.

In the present embodiment, the deformation level of the each unit chip measured in the measuring process is stored in the location information of the unit chip. Such data stored can serve to indicate a deformation level during lamination according to position on an XY plane of the laminated body through simulation.

As in the present embodiment, when the data on the deformation level is stored in the location information of the each unit chip, this stored data on the deformation level allows the deformation level of the each unit chip to be easily estimated according to position in the laminated body. That is, when another laminated body is formed later using this data, a deformation level during lamination can be estimated more easily.

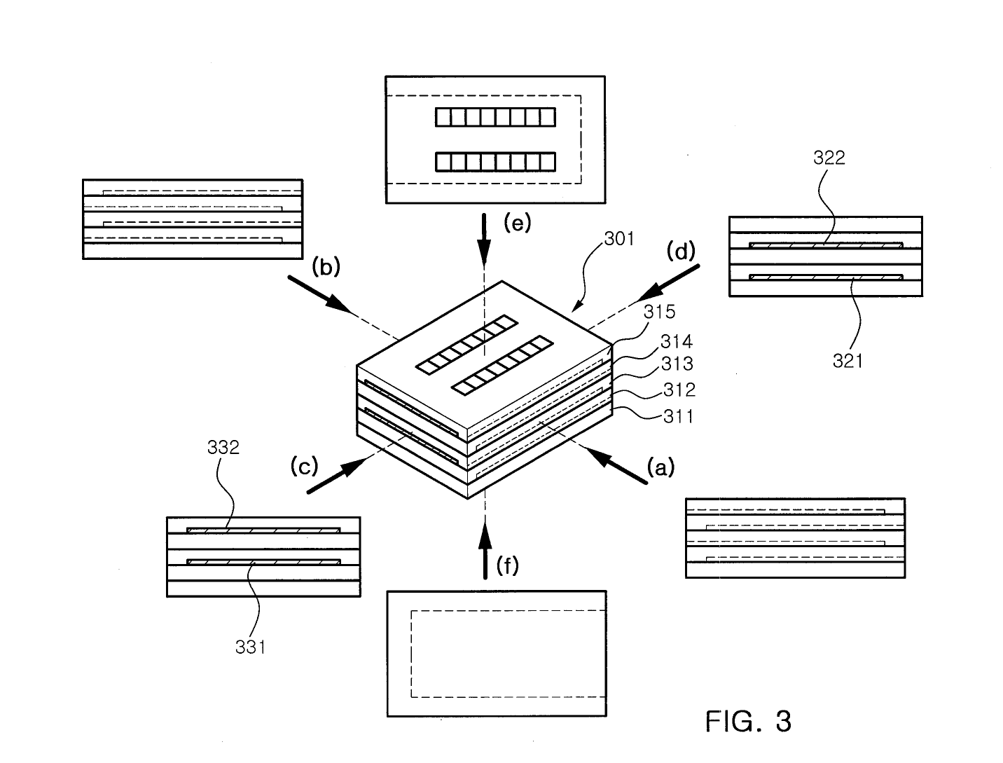

FIG. 3 is a procedural view illustrating a process of measuring a deformation level of a unit chip according to an exemplary embodiment of the invention.

Referring to FIG. 3, in the present embodiment, the unit chip 301 includes plurality of green sheets 311, 312, 313, 314, and 315 laminated therein, and conductor patterns 321, 322, 331, and 332 for internal electrodes formed between corresponding ones of the green sheets. In the present embodiment, the unit chip may be a multilayer ceramic capacitor (MLCC). In order to form the MLCC, out of the internal electrodes formed between the green sheets, a first external electrode is formed to connect to the internal electrodes 321 and 322 exposed at one side surface and a second external electrode is formed to connect to the internal electrodes 331 and 332 exposed at another side surface.

In order to obtain the unit chip 301 of the present embodiment, the laminated body having a plurality of unit chips arranged can be cut. The laminated body is formed by laminating the plurality or green sheets each having the plurality of conductor patterns for internal electrodes. Here, to form the laminated body, the green sheets may be pressurized at a predetermined temperature and pressure. During this pressurization, the conductor patterns for internal electrodes in the laminated body may differ in shape from the conductor patterns for internal electrodes formed on the green sheet. In the unit chip shown in this drawing, the shape of the internal electrodes formed between the green sheets is different from that of the internal electrodes originally designed.

In the present embodiment, a deformation level of the unit chip can be measured by photographing six surfaces of the unit chip. FIG. 3 illustrates the unit chip taken from a front view (a), a rear view (b), a left side view (c), a right side view (d), a plan view (e), and a bottom view (f), respectively.

In a case where the unit chip is taken from a side view and a rear view (a and b), respectively, the internal electrodes disposed between the laminated green sheets are not directly exposed to a surface of the unit chip, but may lead to a difference in shade on the surface of the unit chap. In the present embodiment, shape and position of the internal electrodes in the unit chip can be measured by shade shown when the unit chip is taken from a front view.

In a case where the unit chip is taken from a left side view and a right side view (c and d), respectively, the second internal electrodes 331 and 332 are exposed at a left side of the unit chip and the first internal electrodes 321 and 322 are exposed at a right side of the unit chip. When the MLCC is formed of the unit chips of the present embodiment, the first internal electrodes 321 and 322 and the second internal electrodes 331 and 332 may be connected to the first external electrodes and the external electrodes, respectively. In the present embodiment, the internal electrodes exposed at the left and right sides of the unit chip are photographed to measure the shape and position of the unit chip.

In a case where the unit chip is taken from a plan view and a bottom view (e and f), respectively, the internal electrodes formed between the laminated green sheets are not directly exposed to the surface of the unit chip, but may lead to a difference in shade on the surface of the unit chip. In the present embodiment, the shape and position of the internal electrodes in the unit chip can be measured by shade shown when the unit chip is taken from a front view. Also, when the unit chip is taken from a plan view, the unit chip can have a marking for indicating location information.

As described above, by virtue of the photographed six surfaces of the each divided unit chip, a size difference between the internal electrodes designed and the internal electrodes after actual lamination can serve as data. This data indicating the deformation level according to position of the unit chip can be beneficially utilized in a later process for forming another laminated body.

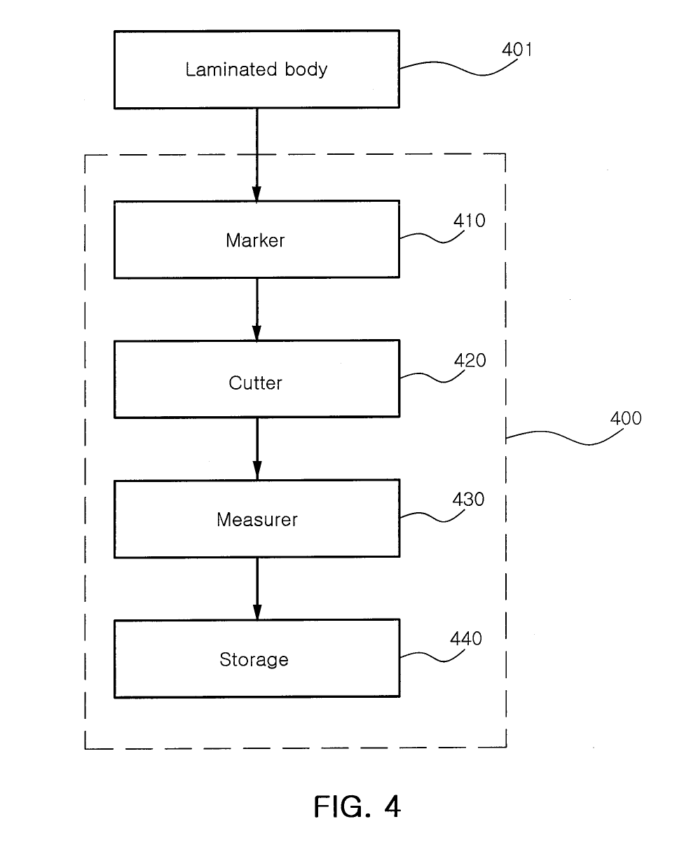

FIG. 4 is a configuration view illustrating an apparatus for measuring deformation of a laminated body according to an exemplary embodiment of the invention;

Referring to FIG. 4, the apparatus 400 for measuring deformation of the laminated body includes a marker 410, a cutter 420, a measurer 430 and a storage 440.

The marker 410 marks location information of each of unit chips on a surface of the laminated body where the plurality of unit chips are arranged.

The each unit may have location information on an XY plane of the laminated body. The each unit chip may be indicated with XY coordinates. The location information formed in the each unit chip indicates in which column and row the unit chip is located on the laminated body.

In the present embodiment, the marker may mark a bar code. This process of marking the location information can be performed by various methods.

The marker may be a laser printer or an ink jet printer. In a case where the location information is marked with a bar code, the bar code can be printed on a predetermined marking area by laser printing or ink jet printing.

The cutter 420 cuts and divides the laminated body having the plurality of unit chips arranged therein into the unit chips.

The cutter 420 cuts and divides the laminated body into the unit chips via a blade. To facilitate this cutting process, indices indicating to-be-cut portions may be formed at side surfaces of the laminated body. For the cutter to perform cutting, the indices are photographed and the blade is positioned where the indices are formed.

Here, to ensure that the blade cuts the indices indicated on the laminated body precisely, the laminated body may be finely rotated to the left and right to be adjusted to a precise position.

The measurer 430 measures a deformation level of the each of the unit chips divided by the cutter. In the present embodiment, the measurer may be a photographing device photographing six surfaces of the divided unit chip.

When the measurer photographs the six surfaces of the divided unit chip, deformation of the internal electrodes formed between the laminated green sheets can be observed. That is, photographing of the side surfaces of the divided unit chip shows a difference in light and shade resulting from the conductor patterns for internal electrodes formed between the laminated green sheets. By this difference in light and shade, shape of the conductor patterns for internal electrodes formed inside the laminated body can be measured. Therefore, this allows for comparison between the conductor patterns for internal electrodes formed on the green sheets before lamination and the conductor patterns for internal electrodes deformed after lamination.

The storage 440 stores the measured deformation level in correspondence with the location information marked on the unit chip.

In the present embodiment, the deformation level of the each unit chip measured by the measurer 430 can be stored in the location information of the unit chip. This stored data can serve as data indicating the deformation level during lamination according to position on an XY plane of the laminated body through simulation.

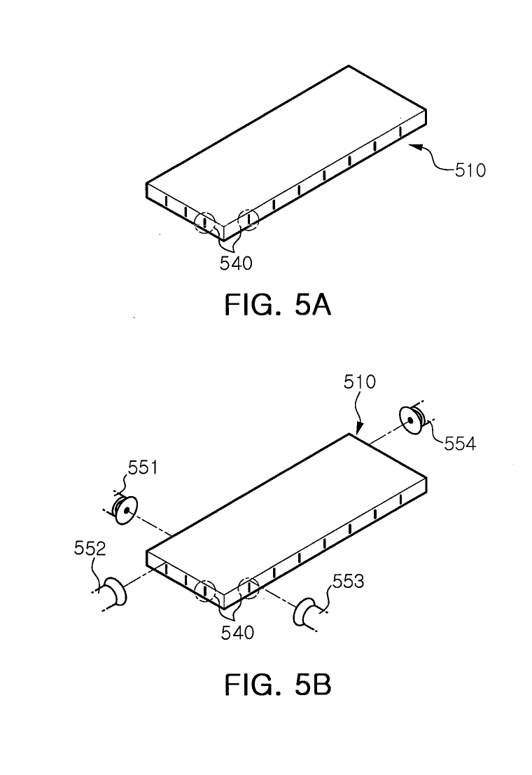

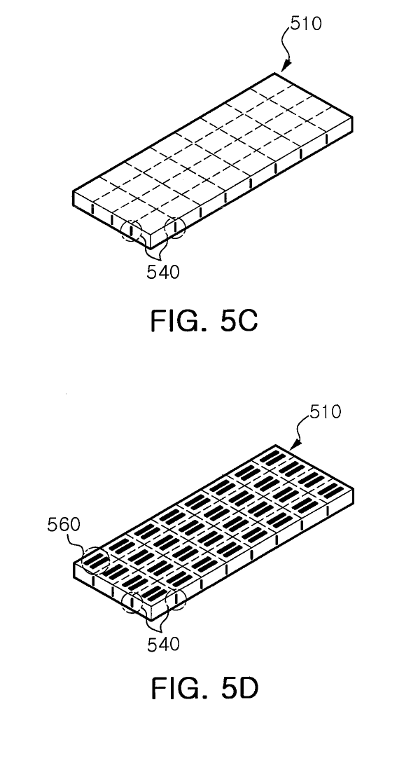

FIGS. 5A to 5D sequentially illustrate a marking process according to an exemplary embodiment of the invention.

Referring to FIGS. 5A to 5D, to perform the marking of the present embodiment, a laminated body is formed in process (5A), indices are recognized in process (5B), a marking area is estimated in process (5C), and marking is performed in process (5D).

Referring to FIG. 5A, the laminated body is formed.

In the present embodiment, the laminated body 510 may be formed by laminating a plurality of green sheets. A plurality of conductor patterns for internal electrodes may be formed on each of the green sheets. The laminated body having the plurality of internal electrode laminated therein can be divided into a plurality of unit chips by the conductor patterns for internal electrodes.

Indices 540 may be formed on the laminated body 510 to divide the laminated body 510 into the plurality of unit chips. The indices may be formed on side surfaces of each of the green sheets of the laminated body. When the indices are indicated in portions of a lamination surface adjacent to the side surfaces of the each green sheet, the indices can be displayed during lamination. The indices may serve as a cutting line for cutting the laminated body into the plurality of unit chips.

The indices may be formed at an identical interval. The indices may be adjusted in interval therebetween in view of an error caused during cutting.

To form the laminated body, a plurality of green sheets are laminated and then pressurized at a predetermined temperature and pressure. At this time, the pressurizing process may cause deformation of the conductor patterns for internal electrodes formed inside the laminated body. In the drawing, deformation of the laminated body is not clearly illustrated but it is construed that an actual measured value of the laminated body has a predetermined difference from a design value of the laminated body.

Referring to FIG. 5B, indices 540 of the laminated body are recognized.

To recognize the indices 540, side surfaces of the laminated body where the indices 540 are indicated are photographed. Images from the photographing allow information of the indices to be recognized.

Referring to FIG. 5C, a marking area of the unit chip in the laminated body is estimated based on information of the recognized indices.

In the present embodiment, portions between two corresponding ones of the indices recognized successively in the laminated body can be defined as a marking area. Dotted lines in the drawing may serve as a cutting line of the laminated body and the marking area of the unit chip is divided by the dotted lines.

Referring to FIG. 5D, location information of each of the unit chips is marked on the estimated marking area.

The marking process may be performed by laser printing or ink jet printing. The location information of the unit chip formed in the marking process may be indicated with a bar code. This marking indicates the location information of the each unit chip on an XY plane of the laminated body.

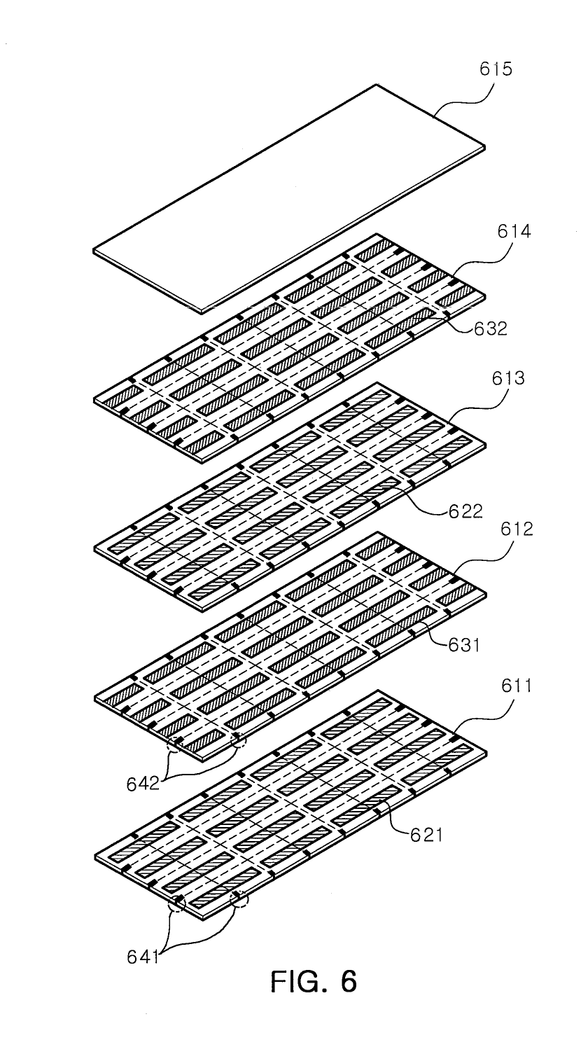

FIG. 6 is an exploded perspective view illustrating a laminated body according to an exemplary embodiment of the invention.

Referring to FIG. 6, the laminated body is formed by laminating a plurality of ceramic green sheets 611, 612, 613, 614, and 615.

Conductor patterns 621, 622, 631, and 632 for internal electrodes may be formed on each of ceramic green sheets. Here, internal electrodes for forming a multilayer ceramic capacitor (MLCC) may be formed on the each green sheet.

In the present embodiment, 8×4 number of unit chips may be formed in a single laminated body. The unit chip formed by cutting the laminated body includes first internal electrodes 621 and 622 and second internal electrodes 631 and 632 alternating between laminated green sheets. The first internal electrodes 621 and 622 and the second internal electrodes 631 and 632 may be exposed at opposing side surfaces of the laminated body. First and second external electrodes are formed to connect to the exposed first and second internal electrodes, respectively to produce a multilayer ceramic capacitor.

Indices 641 and 642 may be formed on each of the green sheets of the laminated body. In the present embodiment, the indices may be formed on a lamination surface of the green sheets. The indices may be formed on portions adjacent to the side surfaces on the laminated surface of the green sheet. When the plurality of green sheets each having the indices formed on the lamination surface are laminated, the indices are displayed on the side surfaces of the laminated body.

The indices may be directly formed on the side surfaces of the each green sheet.

To form the multilayer ceramic capacitor, the laminated body is divided into the unit chips and sintered. When the laminated body is cut along a dotted line as shown in the drawing, a plurality of ceramic capacitor chips each having the first and second internal electrodes exposed to a corresponding one of the side surfaces, respectively can be produced.

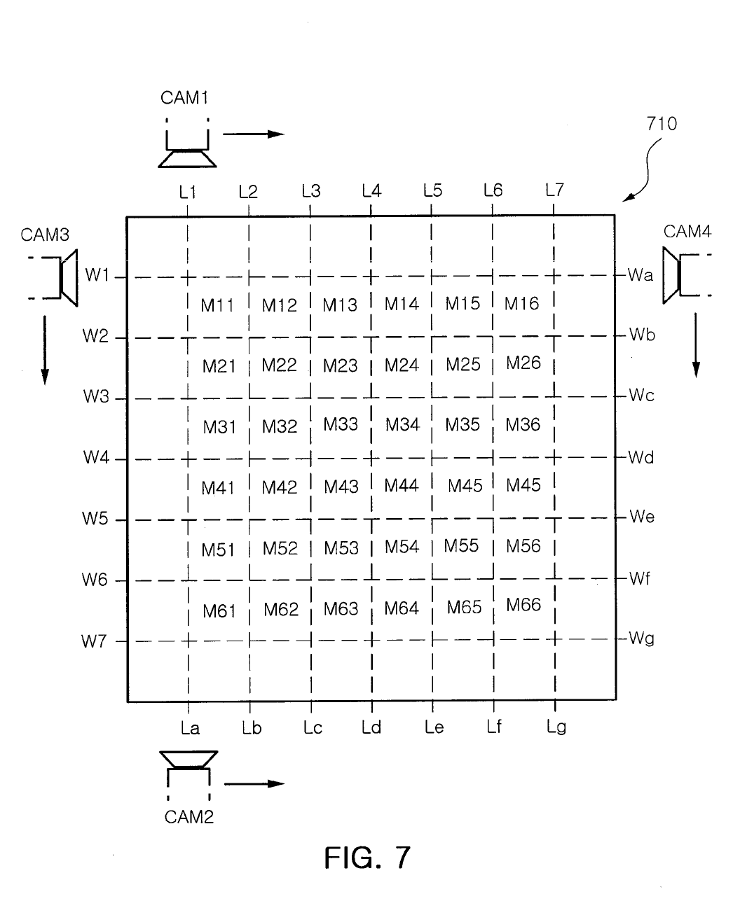

FIG. 7 is a procedural view illustrating a marking process according to an exemplary embodiment of the invention.

Referring to FIG. 7, to perform the marking of the present embodiment, indices are recognized on side surfaces of the laminated body, a marking area is estimated by information on the recognized indices, and location information of each of unit chips is marked on the marking area.

In the laminated body 710, a plurality of unit chips formed by alternately laminated internal electrodes and green sheets are arranged and the indices are indicated on the side surfaces of the laminated body to divide the laminated body into the plurality of unit chips. The indices can be recognized on the side surfaces of the laminated body.

In order to recognize the indices, the four side surfaces of the laminated body may be scanned. In the present embodiment, cameras are installed on the four side surfaces of the laminated body, respectively and the cameras are moved to recognize the indices. To scan the four side surfaces of the laminated body, two cameras may be disposed and the laminated body may be rotated.

In the present embodiment, in order to scan the four side surfaces of the laminated body, respectively, opposing ones of the four side surfaces of the laminated body and the other two opposing side surfaces may be scanned in an identical direction. That is, the first camera CAM1 and the second camera CAM2 located at the opposing side surfaces of the laminated body move from left to right in the laminated body, respectively so that the first camera CAM1 recognizes indices L1 to L7 and the second cameras CAM2 recognizes indices La to Lg. Moreover, the third camera CAM3 and the fourth camera CAM 4 disposed at the other side surfaces of the laminated body move from top to bottom in the laminated body, respectively so that the third camera CAM3 recognizes indices W1 to W7 and the fourth camera CAM4 recognizes indices Wa to Wg.

The first and second cameras may perform scanning simultaneously. The third and fourth cameras may perform scanning simultaneously.

Furthermore, the first and second cameras and the third and fourth cameras may perform scanning simultaneously. As described above, simultaneous scanning of the four side surfaces of the laminated body leads to a greater speed in estimating the marking area of the unit chip.

The marking area of the each unit chip in the laminated body can be estimated based on information on the indices recognized by the plurality of cameras. Here, the marking area is defined by a portion between two corresponding ones of the indices recognized successively.

For example, a first marking area M12 may include a portion between the indices L1 and L2 recognized successively by the first camera CAM1, a portion between the indices La and Lb recognized successively by the second camera CAM2, a portion between the indices W1 and W2 successively recognized by the third camera CAM3 and a portion between the indices Wa and Wb successively recognized by the fourth camera CAM4.

As described above, in the present embodiment, the indices of the four side surfaces of the laminated body are recognized to estimate positions of 6×6 number of marking areas M11 to M66. The number of the marking areas may be varied by the number of indices formed on the laminated body.

As described above, when the marking area of the unit chip of the laminated body is estimated, location information of the unit chip can be marked on the estimated marking area. The marking may be performed by laser printing or ink jet printing. The marking for indicating location information of the unit chip may indicate location information of the unit chip on an XY plane of the laminated body. The location information may be marked with a bar code.

In the present embodiment, as an example of performing the marking, the indices are recognized successively on the four side surfaces of the laminated body, the marking area of the each unit chip is estimated according to the recognized indices and the location information is marked on the each unit chip.

As another example of performing the marking, the laminated body may be divided into predetermined areas and the processes of recognition, estimation and marking may be repeated.

That is, before recognizing the plurality of indices formed on one side surface of the laminated body, the plurality of indices are divided into a plurality of index areas by a predetermined pitch. Then, the processes of recognition, estimation and marking may be carried out according to the divided index areas.

In the present embodiment, 7 indices formed on each of the side surfaces of the laminated body are divided by two pitches to perform the processes of recognition, estimation and marking. That is, a first side surface having the first camera CAM1 disposed thereon is divided into the index areas of L1˜L3, L3˜L5, and L5˜L7. A second side surface having the second camera CAM2 disposed thereon is divided into the index areas of La˜Lc, Lc˜Le, and Le˜Lg. A third side surface having the third camera CAM3 disposed thereon is divided into index areas of W1˜W3, W3˜W5, and W5˜W7. A fourth side surface having the fourth camera CAM4 disposed thereon is divided into index areas of Wa˜Wc, Wc˜We, and We˜Wg.

As described above, the indices are divided into predetermined index areas, and recognition, estimation and marking can be performed separately for each of the index areas. For example, as for the first side surface, first, the indices from L1 to L3 are recognized, a marking area of the unit chip is estimated based on information of the recognized indices and location information of the unit chip is marked. Then, the indices from L3 to L5 are recognized, estimated and marked. As for the second to fourth side surfaces, an identical process may be performed and processes may be carried out simultaneously for the first to fourth side surfaces. In this fashion, recognition, estimation and marking may be performed for a partial area and then recognition, estimation and marking are carried out for the remaining areas. This may slow down the processing speed but reduce an error.

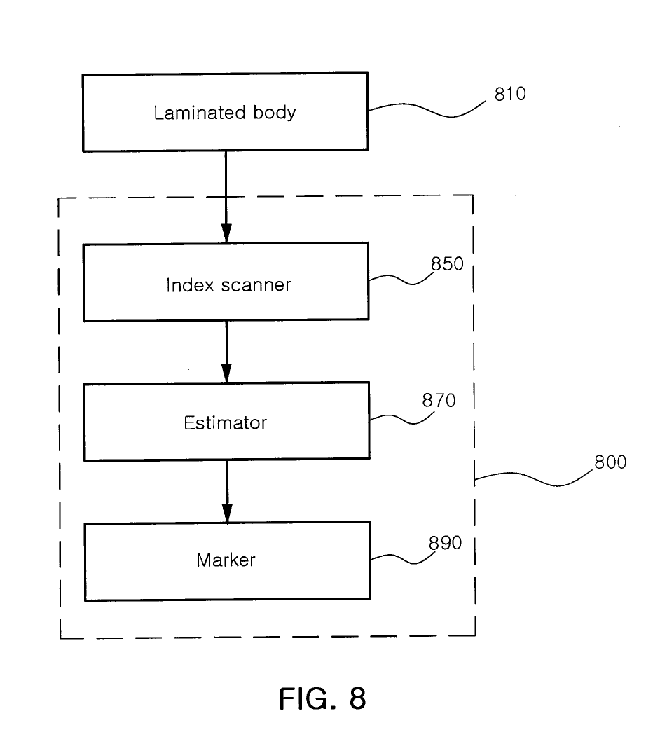

FIG. 8 is a configuration view illustrating a marking apparatus according to an exemplary embodiment of the invention.

Referring to FIG. 8, the marking apparatus 800 includes an index scanner 850, an estimator 870, and a marker 890.

The index scanner 850 recognizes indices formed on the laminated body.

The laminated body has a plurality of unit chips arranged therein and indices formed thereon to divide the unit chips from one another.

The index scanner 850 may be a camera photographing side surfaces of the laminated body having the indices formed thereon to recognize the indices. The camera may be disposed on each of the side surfaces of the laminated body.

The estimator 870 estimates a marking area of the unit chip in the laminated body based on information of the recognized indices.

In the present embodiment, the marking area is defined as a portion between two corresponding ones of the indices of the laminated body recognized successively.

The marker 890 marks the location information of the unit chip on the estimated marking area.

The marker 890 may employ a laser printer or an inkjet printer. By the marker, the location information of the unit chip may be marked with a bar code. This marking may indicate the location information of the each unit chip on a XY plane of the laminated body.

As set forth above, according to exemplary embodiments of the invention, a level of deformation of a laminated body caused by pressurizing conditions during formation of the laminated body can be stored as data and the data can be used as a reference in forming another laminated body later, thereby measuring deformation of the laminated body quantitatively.

While the present invention has been shown and described in connection with the exemplary embodiments, it will be apparent to those skilled in the art that modifications and variations can be made without departing from the spirit and scope of the invention as defined by the appended claims.

What is claimed is:

1. A method of measuring deformation of a laminated body, the method comprising:
laminating and pressurizing a plurality of green sheets each having a plurality of inner electrodes arranged therein to form a laminated body having a plurality of unit chips arranged therein;
marking location information of each of the unit chips on an XY plane of the laminated body on a surface of the unit chip;
cutting the laminated body into the plurality of unit chips;
measuring a deformation level of each of the cut unit chips; and
storing the deformation level measured from the each of the cut unit chips to correspond to the location information of the unit chip.

2. The method of claim 1, wherein the marking comprises performing one of laser printing and ink jet printing.

3. The method of claim 1, wherein the marking comprises printing a bar code indicating the location information of the unit chip.

4. The method of claim 1, wherein the measuring a deformation level comprises photographing six surfaces of the cut unit chip.

5. The method of claim 1, wherein the storing the deformation level comprises storing as data a difference between a design value and a measured value of the unit chip.

6. The method of claim 1, wherein the unit chip is a multilayer ceramic capacitor.

7. An apparatus for measuring deformation of a laminated body, the apparatus comprising:
a marker marking location information of each of a plurality of unit chips on an XY plane of a laminated body where the plurality of unit chips are arranged on a surface of the each of the unit chips;
a cutter cutting the marked laminated body into the unit chips;
a measurer measuring a deformation level of the cut unit chips; and
a storage storing the measured deformation level to correspond to the location information.

8. The apparatus of claim 7, wherein the marker comprises one of a laser printer and an ink jet printer.

9. The apparatus of claim 7, wherein the measurer comprises a photographing device photographing six surfaces of the each of the cut unit chips.

10. A method of marking a laminated body, the method comprising:
forming a laminated body where a plurality of unit chips formed by alternately laminated internal electrodes and green sheets are arranged, the laminated body having indices for separating the unit chips from one another;
recognizing the indices;
estimating a location of a marking area in each of the unit chips which are to be divided, based on information of the recognized indices; and
marking location information of the each unit chip on a XY plane of the laminated body on the estimated marking area.

11. The method of claim 10, wherein the recognizing the indices comprises scanning four side surfaces of the laminated body, respectively.

12. The method of claim 11, wherein the scanning four side surfaces of the laminated body, respectively comprises scanning two opposing ones of the side surfaces and the other two opposing side surfaces in an identical direction, respectively.

13. The method of claim 12, wherein the scanning of the two opposing ones of the side surfaces and the scanning of the other two opposing side surfaces are performed simultaneously.

14. The method of claim 11, wherein the scanning four side surfaces of the laminated body, respectively comprises recognizing all of the indices on one of the side surfaces of the laminated body sequentially.

15. The method of claim 14, wherein the estimating comprises disposing the marking area between the two successively recognized indices.

16. The method of claim 10, further comprising:
dividing the indices into a plurality of index areas by a predetermined pitch; and
repeating the recognizing, the estimating and the marking for each of the divided index areas.

17. A marking apparatus comprising:
an index scanner recognizing indices of a laminated body having the indices for separating unit chips from one another;
an estimator estimating a location of a marking area in each of the unit chips which are to be divided, based on information of the indices recognized by the index scanner; and
marking location information of each of the unit chips on an XY plane of the laminated body on the marking area estimated by the estimator.

18. The marking apparatus of claim 17, wherein the index scanner comprises a photographing device photographing side surfaces of the laminated body.

19. The marking apparatus of claim 17, wherein the marker comprises a laser printer.
